(19) United States
(12) Patent Application Publication
(10) Pub. No.: US 2011/0120545 A1
(43) Pub. Date: May 26, 2011

(54) PHOTOVOLTAIC COMPOSITIONS OR PRECURSORS THERETO, AND METHODS RELATING THERETO

(75) Inventors: BRIAN C. AUMAN, Pickerington, OH (US); Thomas Edward Carney, Orient, OH (US); Kostantinos Kourtakis, Media, PA (US); Salah Boussaad, Wilmington, DE (US)

(73) Assignee: E. I. DU PONT DE NEMOURS AND COMPANY, Wilmington, DE (US)

(21) Appl. No.: 12/623,212

(22) Filed: Nov. 20, 2009

(51) Int. Cl. H01L 31/02; H01L 31/18

(52) U.S. Cl. 136/256; 438/62; 257/E21.085

(57) ABSTRACT

A process for forming at least one photovoltaic component on a substrate is described. The substrate comprises a polyimide and a sub-micron filler. The polyimide is derived substantially or wholly from rigid rod monomers and the sub-micron filler has an aspect ratio of at least 3:1. The substrates of the present disclosure are particularly well suited for photovoltaic applications, due at least in part to high resistance to hygroscopic expansion and relatively high levels of thermal and dimensional stability.

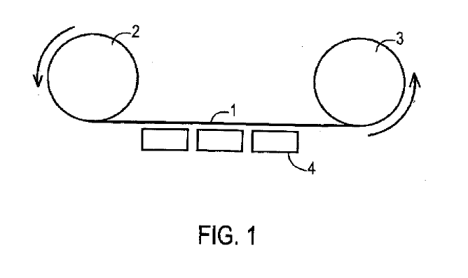

### FIELD OF DISCLOSURE

The present disclosure is directed to substrates useful in the manufacture of thin film photovoltaic cells in a continuous roll to roll process. More specifically, the films of the present disclosure comprise a rigid rod polyimide coupled with a sub-micron, high aspect ratio filler.

### BACKGROUND OF THE DISCLOSURE

Broadly speaking, a photovoltaic cell typically comprises a semiconductor junction device which converts light energy into electrical energy. A typical photovoltaic cell can be described as a layered structure having four principal layers: (1) an absorber-generator (2) a collector-converter (3) a transparent electrical contact, and (4) an opaque electrical contact. When light comes in contact with the absorber-generator, the device generates a voltage differential between the two contacts which generally increases as the intensity of the light increases.

The absorber-generator (the “absorber”) is typically a layer of semiconductor material which absorbs light photons and, as a consequence, generates minority carriers. Typically, the absorber captures photons and ejects electrons thus creating pairs of negatively charged carriers (electrons) and positively charged carriers (“holes”). If the absorber is a p-type semiconductor, the electrons are minority carriers, and if it is n-type, the holes are minority carriers. Minority carriers will be readily annihilated in the absorber (by recombination with the plentiful majority carriers), so the minority carriers must be promptly transported to a collector-converter layer (the “collector”) which is in contact with the absorber layer, wherein the minority become majority carriers once they enter the absorber layer and can thereby be utilized to power an electrical circuit. In other words, the collector layer “collects” minority carriers from the absorber and “converts” them into majority carriers. If the collector is an oppositely doped region of the same semiconductor as the absorber, the photovoltaic device is a p-n junction or homojunction device. If the collector is comprised of a different semiconductor, the device is a heterojunction; and, if the collector is metal, the device is a Schottky junction.

The transparent contact is a conductive electrical contact which permits light to pass through to the absorber. It is typically either a continuous transparent sheet of conductive material or an open grid of opaque conductive material. If the transparent contact is on the same side of the photovoltaic device as the absorber, the device is referred to as being in the front wall configuration. If the transparent contact is on the opposite side, the device is said to be in the back wall configuration.

The advent of silicon junction technology in the 1950's has permitted the development of high cost, high conversion efficiency silicon junction photovoltaic cells. Arrays of such devices have been used with considerable success in the space program. However, the cost of such devices as energy generators can be very high relative to conventional electricity generation. A substantial portion of the high cost is in the preparation of silicon crystals having sufficient purity and also due to the inefficiencies of the batch processes by which such cells are fabricated.

Thin film photovoltaic cells possess many potential advantages over crystalline silicon (wafer based) cells. Photovoltaic cells employing thin films (of materials such as: i. a copper sulfide, copper zinc tin sulfide (CZTS), copper indium gallium diselenide or disulfide (GIGS), among others as an absorber; and ii. a cadmium sulfide or the like as a converter) may be a low cost alternative to silicon crystal based solar cells. A need therefore exists for a method of fabricating durable, reliable thin film solar cells in a low cost continuous process suitable for large scale manufacture.

U.S. Pat. No. 4,318,938 to Barnett et al. is directed to a method for the continuous manufacture of thin film solar cells.

### SUMMARY OF THE INVENTION

The compositions of the present disclosure comprise a filled polyimide substrate. The polyimide substrate has a thickness from about 8 to about 150 microns and contains from about 40 to about 95 weight percent of a polyimide derived from: i. at least one aromatic dianhydride, at least about 85 mole percent of such aromatic dianhydride being a rigid rod dianhydride, ii. at least one aromatic diamine, at least about 85 mole percent of such aromatic diamine being a rigid rod diamine. The polyimide substrates of the present disclosure further comprise a filler having primary particles (as a numerical average) that: i. are less than about 800 nanometers in at least one dimension; ii. have an aspect ratio greater than about 3:1; iii. are less than the thickness of the film in all dimensions; and iv. are present in an amount from about 5 to about 60 weight percent of the total weight of the substrate. The compositions of the present disclosure further comprise photovoltaic components supported by such polyimide substrates.

### BRIEF DESCRIPTION OF THE DRAWING

The FIGURE shows a general schematic of a side view of one embodiment of the present disclosure where the flexible substrate of the present disclosure is arranged in a roll to roll fashion, from supply roll to take-up roll.

### DETAILED DESCRIPTION OF THE PREFERRED EMBODIMENT(S)

### Definitions

“Film” is intended to mean a free-standing film or a coating on a substrate. The term “film” is used interchangeably with the term “layer” and refers to covering a desired area.

“Monolithic integration” is intended to mean integrating (either in series or in parallel) a plurality of photovoltaic cells to form a photovoltaic module, where the cells/module can be formed in a continuous fashion on a single film or substrate, e.g., a reel to reel operation.

“Semiconductor” is intended to mean any semiconductive material, particularly amorphous silicon or microcrystalline silicon, but also including any of the following:
1. Group IV semiconductors (silicon, germanium, diamond);
2. Group IV compound semiconductors (SiGe, SiC);
3. Group III-V semiconductors (AlSb, AlAs, AlN, AlP, BN, BP, BAs, GaSb, GaAs, GaN, GaP, InSb, InAs, InN, InP);
4. Group III-V semiconductor alloys (AlGaAs, InGaAs, InGaP, AlInAs, AlInAs, AlInSb, GaAsN, GaAsP, AlGaN, AlGaP, InGaN, InAsSb, InGaSb);
5. III-V quaternary semiconductor alloys (AlGaInP, AlGaAsP, InGaAsP, InGaAsP, AlInAsP, AlGaAsN, InGaAsN, InAlAsN, GaAsSbN);
6. III-V quinary semiconductor alloys (GaInNAsSb, GaInAsSbP):
7. II-VI semiconductors (CdSe, CdS, CdTe, ZnO, ZnSe, ZnS, ZnTe);
8. II-VI ternary alloy semiconductors (CdZnTe, HgCdTe, HgZnTe, HgZnSe);
9. I-VII semiconductors (CuCl);
10. IV-VI semiconductors (PbSe, PbS, PbTe, SnS, SnTe);
11. IV-VI ternary semiconductors (PbSnTe, Tl₂SnTe₅, Tl₂GeTe₅);
12. V-VI semiconductors (Bi₂Te₃₎;
13. II-V semiconductors (Cd₃P₂, Cd₃As₂, Cd₃Sb₂, Zn₃P₂, Zn₃As₂, Zn₃Sb₂);
14. layered semiconductors (PbI₂, MoS₂, GaSe, SnS, Bi₂S₃),
15. others (CuInGaSe₂, CuInGaS₂, CuZnSnS₄, PtSi, BiI₃, HgI₂, TlBr);
16. and the like.

“Dianhydride” as used herein is intended to also include precursors and derivatives of (or otherwise compositions related to) dianhydrides, which may not technically be dianhydrides but are nevertheless functionally equivalent due to the capability of reacting with a diamine to form a polyamic acid which in turn could be converted into a polyimide.

Similarly, “diamine” is intended to also include precursors and derivatives of (or otherwise compositions related to) diamines, which may not technically be diamines but are nevertheless functionally equivalent due to the capability of reacting with a dianhydride to form a polyamic acid which in turn could be converted into a polyimide.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

The support films of the present disclosure resist shrinkage or creep (even under tension, such as, reel to reel processing) within a broad temperature range, such as, from about room temperature to temperatures in excess of 400° C., 425° C. or 450° C. In one embodiment, the support film of the present disclosure changes in dimension by less than 1, 0.75, 0.5, or 0.25 percent when subjected to a temperature of 450° C. for 30 minutes while under a stress in a range from 7.4-8.0 MPa (mega Pascals).

The polyimide support films of the present disclosure can be reinforced with thermally stable, inorganic: fabric, paper (e.g., mica paper), sheet, scrim or combinations thereof. The support films of the present disclosure have adequate electrical insulation or otherwise dielectric properties properties for TFT applications. In some embodiments, the support films of the present disclosure provide:
i. low surface roughness, i.e., an average surface roughness (Ra) of less than 1000, 750, 500, 400, 350, 300 or 275 nanometers;
ii. low levels of surface defects; and/or
iii. other useful surface morphology, to diminish or inhibit unwanted defects, such as, electrical shorts.

In one embodiment, the films of the present disclosure have an in-plane CTE in a range between (and optionally including) any two of the following: 1, 5, 10, 15, 20, and 25 ppm/° C., where the in-plane coefficient of thermal expansion (CTE) is measured between 50° C. and 350° C. In some embodiments, the CTE within this range is further optimized to further diminish or eliminate unwanted cracking due to thermal expansion mismatch of any particular supported semiconductor material selected in accordance with the present disclosure. Generally, when forming the polyimide, a chemical conversion process (as opposed to a thermal conversion process) will provide a lower CTE polyimide film. This is particularly useful in some embodiments, as very low CTE (<10 ppm/° C.) values can be obtained, closely matching those of the delicate conductor and semiconductor layer deposited thereon. Chemical conversion processes for converting polyamic acid into polyimide are well known and need not be further described here. The thickness of a polyimide support film can also impact CTE, where thinner films tend to give a lower CTE (and thicker films, a higher CTE), and therefore, film thickness can be used to fine tune film CTE, depending upon any particular application selected.

The films of the present disclosure have a thickness in a range between (and optionally including) any of the following thicknesses (in microns): 4, 6, 8, 10, 12, 15, 20, 25, 50, 75, 100, 125 and 150 microns. Monomers and fillers within the scope of the present disclosure can also be selected or optimized to fine tune CTE within the above range. Ordinary skill and experimentation may be necessary in fine tuning any particular CTE of the polyimide films of the present disclosure, depending upon the particular application selected. The in-plane CTE of the polyimide film of the present disclosure can be obtained by thermomechanical analysis utilizing a TA Instruments TMA-2940 run at 10° C./min, up to 380° C., then cooled and reheated to 380° C., with the CTE in ppm/° C. obtained during the reheat scan between 50° C. and 350° C.

The polyimide support films of the present disclosure should have high thermal stability so the films do not substantially degrade, lose weight, have diminished mechanical properties, or give off significant volatiles, e.g., during the photovoltaic layer deposition process. The polyimide support films of the present disclosure should be thin enough to not add excessive weight or cost, but thick enough to provide high electrical insulation at operating voltages, which in some cases may reach 400, 500, 750 or 1000 volts or more.

In accordance with the present disclosure, a filler is added to the polyimide film to increase the polyimide storage modulus. In some embodiments, the filler of the present disclosure will maintain or lower the coefficient of thermal expansion (CTE) of the polyimide layer while still increasing the modulus. In some embodiments, the filler increases the storage modulus above the glass transition temperature (Tg) of the polyimide film. The addition of filler typically allows for the retention of mechanical properties at high temperatures and can improve handling characteristics. The fillers of the present disclosure:
1. have a dimension of less than 800 nanometers (and in some embodiments, less than 750, 650, 600, 550, 500, 475, 450, 425, 400, 375, 350, 325, 300, 275, 250, 225, or 200 nanometers) in at least one dimension (since fillers can have a variety of shapes in any dimension and since filler shape can vary along any dimension, the “at least one dimension” is intended to be a numerical average along that dimension);
2. have an aspect ratio greater than 3, 4, 5, 6, 7, 8, 9, 10, 11, 12, 13, 14, or 15 to 1 ;
3. is less than 100, 95, 90, 85, 80, 75, 70, 65, 60, 55, 50, 45, 40, 35, 30, 25, 20, 15 or 10 percent of the thickness of the film in all dimensions; and
4. is present in an amount between and optionally including any two of the following percentages: 5, 10, 15, 20, 25, 30, 35, 40, 45, 50, 55, and 60 weight percent, based upon the total weight of the film.

Suitable fillers are generally stable at temperatures above 450° C., and in some embodiments do not significantly decrease the electrical insulation properties of the film. In some embodiments, the filler is selected from a group consisting of needle-like fillers, fibrous fillers, platelet fillers and mixtures thereof. In one embodiment, the fillers of the present disclosure exhibit an aspect ratio of at least 3, 4, 5, 6, 7, 8, 9, 10, 11, 12, 13, 14, or 15 to 1. In one embodiment, the filler aspect ratio is 6:1 or greater. In another embodiment, the filler aspect ratio is 10:1 or greater, and in another embodiment, the aspect ratio is 12:1 or greater. In some embodiments, the filler is selected from a group consisting of oxides (e.g., oxides comprising silicon, titanium, magnesium and/or aluminum), nitrides (e.g., nitrides comprising boron and/or silicon) or carbides (e.g., carbides comprising tungsten and/or silicon). In some embodiments, the filler comprises oxygen and at least one member of the group consisting of aluminum, silicon, titanium, magnesium and combinations thereof. In some embodiments, the filler comprises platelet talc, acicular titanium dioxide, and/or acicular titanium dioxide, at least a portion of which is coated with an aluminum oxide. In some embodiments, the filler is less than 50, 25, 20, 15, 12, 10, 8, 6, 5, 4, or 2 microns in all dimensions.

In yet another embodiment, carbon fiber and graphite can be used in combination with other fillers to increase mechanical properties. However, oftentimes care must be taken to keep the loading of graphite and/or carbon fiber below 10%, since graphite and carbon fiber fillers can diminish insulation properties and in many embodiments, diminished electrical insulation properties is not desirable. In some embodiments, the filler is coated with a coupling agent. In some embodiments, the filler is coated with an aminosilane coupling agent. In some embodiments, the filler is coated with a dispersant. In some embodiments, the filler is coated with a combination of a coupling agent and a dispersant. Alternatively, the coupling agent and/or dispersant can be incorporated directly into the film and not necessarily coated onto the filler.

In some embodiments, a filtering system is used to ensure that the final film will not contain discontinuous domains greater than the desired maximum filler size. In some embodiments, the filler is subjected to intense dispersion energy, such as agitation and/or high shear mixing or media milling or other dispersion techniques, including the use of dispersing agents, when incorporated into the film (or incorporated into a film precursor) to inhibit unwanted agglomeration above the desired maximum filler size. As the aspect ratio of the filler increases, so too does the tendency of the filler to align or otherwise position itself between the outer surfaces of the film, thereby resulting in a increasingly smooth film, particularly as the filler size decreases.

Generally speaking, film smoothness is desirable in the TFT applications of the present disclosure, since surface roughness can interfere with the functionality of the layer or layers deposited thereon, can increase the probability of electrical or mechanical defects and can diminish property uniformity along the film. In one embodiment, the filler (and any other discontinuous domains) are sufficiently dispersed during film formation, such that the filler (and any other discontinuous domains) are sufficiently between the surfaces of the film upon film formation to provide a final film having an average surface roughness (Ra) of less than 1000, 750, 500 or 400 nanometers. Surface roughness as provided herein can be determined by optical surface profilometry to provide Ra values, such as, by measuring on a Veeco Wyco NT 1000 Series instrument in VSI mode at 25.4x or 51.2x utilizing Wyco Vision 32 software.

In some embodiments, the filler is chosen so that it does not itself degrade or produce off-gasses at the desired processing temperatures. Likewise in some embodiments, the filler is chosen so that it does not contribute to degradation of the polymer.

Useful polyimides of the present disclosure are derived from: i. at least one aromatic diamine, at least 85, 90, 95, 96, 97, 98, 99, 99.5 or 100 mole percent being a rigid rod type monomer; and ii. at least one aromatic dianhydride, at least 85, 90, 95, 96, 97, 98, 99, 99.5 or 100 mole percent being a rigid rod type monomer. Suitable rigid rod type, aromatic diamine monomers include: 1,4-diaminobenzene (PPD), 4,4′-diaminobiphenyl, 2,2′-bis(trifluoromethyl)benzidene (TFMB), 1,4-naphthalenediamine, and/or 1,5-naphthalenediamine. Suitable rigid rod type, aromatic dianhydride monomers include pyromellitic dianhydride (PMDA), and/or 3,3′,4,4′-biphenyl tetracarboxylic dianhydride (BPDA).

In some embodiments, other monomers may also be considered for up to 15 mole percent of the aromatic dianhydride and/or up to 15 mole percent of the aromatic diamine, depending upon desired properties for any particular application of the present invention, for example: 3,4′-diaminodiphenyl ether (3,4′-ODA), 4,4′-diaminodiphenyl ether (4,4′-ODA), 1,3-diaminobenzene (MPD), 4,4′-diaminodiphenyl sulfide, 9,9′-bis(4-aminophenyl)fluorene, 3,3′,4,4′-benzophenone tetracarboxylic dianhydride (BTDA), 4,4′-oxydiphthalic anhydride (ODPA), 3,3′,4,4′-diphenyl sulfone tetracarboxylic dianhydride (DSDA), 2,2-bis(3,4-dicarboxyphenyl)hexafluoropropane dianhydride (6FDA), and mixtures thereof. Polyimides of the present disclosure can be made by methods well known in the art and their preparation need not be discussed in detail here.

In some embodiments, the film is manufactured by incorporating the filler into a film precursor material, such as, a solvent, monomer, prepolymer and/or polyamic acid composition. Ultimately, a filled polyamic acid composition is generally cast into a film, which is subjected to drying and curing (chemical and/or thermal curing) to form a filled polyimide free-standing or non free-standing film. Any conventional or non-conventional method of manufacturing filled polyimide films can be used in accordance with the present disclosure. The manufacture of filled polyimide films is well known and need not be further described here. In one embodiment, the polyimide of the present disclosure has a high glass transition temperature (Tg) of greater than 300, 310, 320, 330, 340, 350, 360, 370 380, 390 or 400° C. A high Tg generally helps maintain mechanical properties, such as storage modulus, at high temperatures.

In some embodiments, the crystallinity and amount of crosslinking of the polyimide support film can aid in storage modulus retention. In one embodiment, the polyimide support film storage modulus (as measured by dynamic mechanical analysis, DMA) at 480° C. is at least: 400, 450, 500, 550, 600, 650, 700, 750, 800, 850, 900, 950, 1000, 1100, 1200, 1300, 1400, 1500, 1600, 1800, 2000, 2200, 2400, 2600, 2800, 3000, 3500, 4000, 4500, or 5000 MPa.

In some embodiments, the polyimide support film of the present disclosure has an isothermal weight loss of less than 1, 0.75, 0.5 or 0.3 percent at 500° C. over about 30 minutes in an inert atmosphere.

Polyimides of the present disclosure have high dielectric strength, generally higher than common inorganic insulators. In some embodiments, polyimides of the present disclosure have a breakdown voltage equal to or greater than 10 V/micrometer. In some embodiments the filler is selected from a group consisting of oxides, nitrides, carbides and mixtures thereof, and the film has at least 1, 2, 3, 4, 5, or all 6 of the following properties: i. a Tg greater than 300° C., ii. a dielectric strength greater 500 volts per 25.4 microns, iii. an isothermal weight loss of less than 1% at 500° C. over 30 minutes in an inert atmosphere, iv. an in-plane CTE of less than 25 ppm/° C., v. an absolute value stress free slope of less than 10 times (10)⁻⁶ perminute, and vi. an eₘₐₓ of less than 1% at 7.4-8 MPa. In some embodiments, the film of the present disclosure is reinforced with a thermally stable, inorganic: fabric, paper, sheet, scrim or a combination thereof.

In some embodiments, electrically insulating fillers may be added to modify the electrical properties of the film. In some embodiments, it is important that the polyimide support film be free of pinholes or other defects (foreign particles, gels, filler agglomerates or other contaminates) that could adversely impact the electrical integrity and dielectric strength of the polyimide support film, and this can generally be addressed by filtering. Such filtering can be done at any stage of the film manufacture, such as, filtering solvated filler before or after it is added to one or more monomers and/or filtering the polyamic acid, particularly when the polyamic acid is at low viscosity, or otherwise, filtering at any step in the manufacturing process that allows for filtering. In one embodiment, such filtering is conducted at the minimum suitable filter pore size or at a level just above the largest dimension of the selected filler material.

A single layer film can be made thicker in an attempt to decrease the effect of defects caused by unwanted (or undesirably large) discontinuous phase material within the film. Alternatively, multiple layers of polyimide may be used to diminish the harm of any particular defect (unwanted discontinuous phase material of a size capable of harming desired properties) in any particular layer, and generally speaking, such multilayers will have fewer defects in performance compared to a single polyimide layer of the same thickness. Using multiple layers of polyimide films can diminish or eliminate the occurrence of defects that may span the total thickness of the film, because the likelihood of having defects that overlap in each of the individual layers tends to be extremely small. Therefore, a defect in any one of the layers is much less likely to cause an electrical or other type failure through the entire thickness of the film. In some embodiments, the polyimide support film comprises two or more polyimide layers. In some embodiments, the polyimide layers are the same. In some embodiments, the polyimide layers are different. In some embodiments, the polyimide layers independently may comprise a thermally stable filler, reinforcing fabric, inorganic paper, sheet, scrim or combinations thereof. Optionally, 0-60 weight percent of the film also includes other ingredients to modify properties as desired or required for any particular application.

The aforementioned properties of the polyimide substrates of the present disclosure are well adapted for use in a roll-to-roll process, in which deposition of additional layers in the manufacture of photovoltaic cells can be effected on a continuous web of the polyimide substrate. While the invention will now be illustrated with specific embodiments, it will be understood that it is not intended to limit the invention to the described embodiments. On the contrary, it is intended to cover alternatives, modifications, and equivalents as may be included within the spirit and scope of the invention as defined by the appended claims.

The above described polyimide substrates of the present disclosure are well suited for use as a photovoltaic device substrate. The polyimide substrate is filled and can be opaque or (wholly or partially) transparent. The substrate may comprise any shape, thickness, width or length suitable for the process described herein. The substrate may comprise leaders or “breaks” where the substrate is spliced together with any suitable material and still comprise a continuous “length” in accordance with this invention. Optionally, the substrate may comprise a laminate of one or more materials, and in one embodiment the laminate is a polyimide support substrate as described above, supporting a conductive material, such as, a metal layer.

The substrate may have any number of holes placed therein by any process for a variety of uses. Preferably the flexible substrate serves as the substrate of the photovoltaic device according to the process of the invention. The flexible substrate may serve as an electrode, e.g., a laminate comprising an electrode material in one layer. The substrate may have a first side and an opposite second or back-side. When the substrate is used as a substrate herein it can be about 12 microns to 150 microns, and generally about 25-50 microns to conveniently function as a substrate in most applications. By “roll to roll” it is meant that the process be fed with a roll of flexible substrate and that the process comprise a take up roll around which is wound the completed (or substantially completed) flexible solar cell. The invention contemplates that the flexible substrate may travel in both directions in the roll to roll configuration.

By “series of deposition sources capable of forming layers on the flexible substrate” it is meant at least two “deposition sources” capable of depositing or otherwise creating layers or etching, scribing or otherwise acting on the flexible substrate. By “forming a layer” it is meant those steps for depositing, etching, reacting scribing or otherwise creating or adding to a layer, or acting on a layer already present. “Depositing a layer” shall include those step or steps for forming, reacting, etching and/or scribing a layer which includes PVD, CVD, evaporation, sputtering and sublimation. “Deposition sources” as used herein is broadly meant to include those apparatus and materials capable of creating or forming the layers by, but not limited to, physical and chemical vapor deposition apparatus. Also, the invention contemplates that “deposition sources” and shall also include apparatus and materials for forming, reacting, etching and/or scribing or otherwise acting or performing chemical reactions on the layers of the photovoltaic device to create or alter a layer or layers.

By “free span” it is meant allowing processing of the substrate without the use of a drum. In one embodiment of the present invention the substrate is worked on by multiple deposition apparatus on the first and second sides of the substrate, at the same time if so desired. “Free span” does not limit the entire process of the invention drum free, though that is an embodiment, but contemplates the use at least one drumless deposition processes. There may be a drum process in a chamber with a free span configuration in some embodiments, or there may be no drums in any of the chamber(s). There is known in the art multi-rolls suitable for this purpose which may aid in the guiding and tensioning of the substrate. “Vacuum chamber” as used herein is meant to include a chamber having the ability of controlling the pressure through those means known in the art. By “photovoltaic device” as used herein it is meant a multilayered structure having the least amount of layers necessary where in a working environment with proper leads and connections is capable of converting light into electricity. Preferably the device contains at least the following layers in order: a substrate/electrode layer/absorber layer/window layer and a TCO (transparent conductive oxide) layer.

In one embodiment the photovoltaic device has a superstrate configuration and the device has at least the following layers a in order: polyimide film substrate/TCO/window layer/absorber layer/electrode layer. In a superstrate configuration the substrate may be transparent or opaque. In one embodiment the substrate comprises a metal and is opaque. In one embodiment, there is an interface layer between the absorber layer and the electrode layer. The device may have any further structure necessary to practically utilize the device such as leads, connections, etc. The above preferred embodiments of the present invention do not limit the order of layers or deposition order of the photovoltaic device. When it is recited “forming a set of multiple layers comprising a first photovoltaic device” the invention is not limited to exactly the order of deposition of any particular set of layers or to the layer order on the substrate.

By “set of multiple layers” it is meant the minimum amount and of layers having the correct composition necessary that when properly placed in service is capable of acting as a solar device, i.e. converting light into electricity.

As used herein the word “continuous” means the formation of at least one set of multiple layers onto a length of flexible substrate in a process where a substrate is passed past a set of deposition sources for forming the layers in a process where the running length of flexible substrate that serves as a substrate extends continuously from an input source (supply roll) to a take up roll or other means for ending the process, while passing a set of deposition sources. The invention also contemplates that “continuous” may mean the backwards or opposite travel of the flexible substrate past a set of deposition sources. This embodiment is useful for a variety of purposes, including reprocessing.

“Means for transporting a flexible substrate” as used herein includes take up and supply rolls to effectuate a roll to roll system, a roll to sheet system, or a free span configuration including multi-rolls in any number or shape or configuration or a system including any combination of the above. It also includes a drum as discussed herein. Any of the drum, supply roll, take up roll, multi-roll may be free rolling or mechanically driven and controlled by the system computer. “Means for forming multiple layers on the flexible substrate” includes physical and vapor deposition sources and apparatus, etching, scribing, patterning, cleaning and other such processes and apparatus as disclosed herein to affect a change, create or react any or all of the layers. “Means for independently controlling each deposition source” includes those techniques in the art for controlling multiple deposition processes including but not required or limited to computers with the accompanying software.

In one embodiment of the present disclosure, photovoltaic devices comprise a substrate layer/electrode layer/absorber layer/window layer/TCO layer, where TCO stands for transparent conductive oxide. In one embodiment, there is an interface layer between the electrode and absorber layer resulting in a structure: substrate layer/electrode layer/barrier interface layer/absorber layer/window layer/TCO layer. In one embodiment the electrode (conductor) is typically a metal (Al, Mo, Ti, etc.) but can be a semiconductor such as ZnTe. The metal electrode has a thickness of about 200 nm to 2,000 nm, preferably about 500 nm. Interface layer materials are known in the art and any suitable material such as ZnTe or similar materials that provide advantages in contacting absorber materials such as CdTe and/or CIGS which do not easily form ohmic contacts directly with metals. The electrode metals are typically deposited by sputtering. Planar or rotatable magnetrons may be used. The interface layer can be deposited by a similar method or by evaporation. In one embodiment of the present invention sputtering these two layers can be accomplished in a single chamber, with the substrate either on a temperature-controlled drum or in free-span. This can provide advantages for the substrate handling and heat load.

In one embodiment of the present disclosure after the electrode and interface layer are deposited, the flexible substrate travels through another chamber. Differentially pumped slits for environment isolation between chambers may be used. In one embodiment the absorber layer can be deposited by sputtering or other physical vapor deposition (PVD) methods known in the art for this purpose, such as close space sublimation (CSS), vapor transport deposition (VTD), evaporation, close-space vapor transport (CSVT) or similar PVD method or by chemical vapor deposition (CVD) methods. The absorber layer may comprise compounds selected from the group consisting of Group II-VI, Group I-III-VI and Group IV compounds. Group II-VI compounds include ZnS, ZnSe, ZnTe, CdS, CdSe, CdTe, HgS, HgSe, HgTe, MgTe and the like. Preferred are Group

II-VI compounds and particularly preferred is CdTe.

In one embodiment the absorber material can be deposited while controlling the substrate, typically at temperatures of about 400° C. In some embodiments, the absorber comprises CdTe, copper zinc tin sulfide (CZTS) or CIGS. CIGS is copper indium gallium diselenide or disulfide, e.g., CuInₓGa₁₋ₓSe, where 0(< or =) x<1. Included herein includes the family of materials generally referred as CIGS include CIS, CISe, CIGSe, CIGSSe. The CdTe absorber layer thickness is about 1 micron to 10 microns, e.g., about 5 microns. The CIGS absorber thickness is about 0.5 microns to 5 microns, e.g., about 2 microns.

Following deposition of the absorber layer, a window layer can be deposited by similar PVD methods. Window layer(s) may comprise CdS, ZnS, CdZnS, ZnSe, In₂S₃, and/or any conventional or nonconventional, known or future discovered window layer material. In one embodiment CdS is the window layer material and may be deposited by those techniques known in the art such as CSS or VTD. The CdS window layer thickness can be about 50 nm to 200 nm, e.g., about 100 nm. Subsequent to the window layer deposition a post-process grain growth step is contemplated, such as a CdCl₂ treatment which is known in the art for CdTe grain growth. This can be either before or after CdS deposition and in some embodiments occur in the same deposition chamber as the absorber or could occur in a third, isolated chamber.

In one embodiment following the absorber and window layer deposition and absorber post-deposition grain growth step, the TCO can be deposited by PVD methods, for example sputtering. Common TCO's known in the art for this purpose include ZnO, ZnO:Al, ITO, SnO₂ and CdSnO₄. ITO is In₂O₃ containing 10% of Sn. The TCO thickness is about 200 nm to 2,000 nm, preferably about 500 nm.

The present disclosure contemplates the deposition of additional layers if desired. Non-limiting examples include a top metal contact in a grid-like pattern for improved solar cell device performance. Once completed, the flexible solar cell can be re-rolled onto a take-up spool. This method is either semi-continuous or continuous depending on whether a new flexible substrate leader is spliced into the previous flexible substrate tail to maintain a continuous flexible substrate. In one embodiment the flexible substrate may be initially threaded through the system, run through the processes and then dismounted. This means opening the system each time a flexible substrate is to be started in order to thread the flexible substrate through the system. With periodic maintenance being required on such a system the length of flexible substrate may be synchronized with the maintenance schedule such that this does not impact system up time and process throughput.

Care should be taken in the manufacture of the photovoltaic devices made in accordance with the present disclosure to obtain necessary layer cohesion over the length of the substrate which may be 500 meters long or longer. In addition, care should be taken that the layers exhibit a consistent stoichiometric composition, as desired.

In one embodiment the cells can be integrated in situ into a module in a monolithic integration scheme. This contemplates the use of laser and/or mechanical scribing tools internal to the system. The present disclosure contemplates that the location of scribing processes can be variable within the system. In one embodiment the first scribe may be positioned after the back electrode and the barrier interface layer have been deposited, immediately prior to the absorber deposition. In another embodiment, the second scribe is located directly after the high-resistivity ZnO layer, just prior to the ZnO:Al or low-resistivity TCO layer deposition. The third and final scribe may, in one embodiment be placed after the low-resistivity TCO but, as this is the final layer in some embodiments, could be done outside the fabrication system on a separate stand-alone system, or perhaps in-line with subsequent process tools such as slitting/sheeting, contacting or packaging. Scribes may be placed in front of and in back of the substrate.

In one embodiment treatment or annealing in a reducing atmosphere such as H₂ or forming gas is contemplated. Alternatively treatment or annealing in an oxidizing atmosphere such as O₂ containing, HCl containing, nitric oxide containing atmospheres is also contemplated within the processes of the present disclosure.

In one embodiment of the present disclosure, the fabrication system provides for no front-side touching of the substrate. In one embodiment all layers are deposited by PVD methods including sputtering, evaporation, close-space sublimation, closed space vapor transport, vapor transport deposition or other such methods.

The invention will now be described with reference to particular embodiments referring to the FIGURE. The FIGURE shows a general schematic according to one embodiment of the present invention. A flexible substrate 1 is arranged in a roll to roll fashion from supply roll 2 to take-up roll 3. Between supply roll 2 and take-up roll 3 is a deposition zone or material source zone wherein evaporation-type deposition sources 4, including traditional evaporation, close-space sublimation, vapor transport, close-space vapor transport and chemical vapor are located. In this deposition zone the layers of a thin-film solar cell, such as CdTe, are deposited by physical vapor or chemical vapor deposition means onto the passing flexible substrate in a continuous manner. The invention contemplates that deposition may occur while the substrate is moving past the sources at any a speed suitable to adequately form the required layer in size and composition.

Alternatively, the deposition process may include a step where the substrate is temporarily stationary inside the chamber, said stationary step programmed to affect a particular process enacted upon the substrate. The flexible substrate may be maintained at any tension suitable to accomplish the particular deposition or scribing, etc. process in that particular chamber. The speed may not be steady state, but may vary depending on the process. It is understood that the invention is not limited to a roll-to-roll for supply and take up of the substrate. For example the take up roll may be substituted for another means, such as a cut and stack apparatus. Similarly the supply roll may be substituted with other means.

It is understood that the embodiments described herein disclose only illustrative but not exhaustive examples of the layered structures possible by the present invention. Intermediate and/or additional layers to those disclosed herein are also contemplated and within the scope of the present invention. Coating, sealing and other structural layers are contemplated where end use of the photovoltaic device warrants such construction.

### EXAMPLES

The invention will be further described in the following examples, which are not intended to limit the scope of the invention described in the claims. In these examples, “prepolymer” refers to a lower molecular weight polymer made with a slight stoichiometric excess of diamine monomer (ca. 2%) to yield a Brookfield solution viscosity in the range of about 50-100 poise at 25° C. Increasing the molecular weight (and solution viscosity) was accomplished by adding small incremental amounts of additional dianhydride in order to approach stoichiometric equivalent of dianhydride to diamine.

### Example 1

BPDA/PPD prepolymer (69.3 g of a 17.5 wt % solution in anhydrous DMAC) was combined with 5.62 g of acicular TiO₂ (FTL-110, Ishihara Corporation, USA) and the resulting slurry was stirred for 24 hours. In a separate container, a 6 wt % solution of pyromellitic anhydride (PMDA) was prepared by combining 0.9 g of PMDA (Aldrich 412287, Allentown, Pa.) and 15 ml of DMAC.

The PMDA solution was slowly added to the prepolymer slurry to achieve a final viscosity of 653 poise. The formulation was stored overnight at 0° C. to allow it to degas.

The formulation was cast using a 25 mil doctor blade onto a surface of a glass plate to form a 3″×4″ film. The glass was pretreated with a release agent to facilitate removal of the film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:

| | |
|---|---|
| 125° C. | (30 min) |
| 125° C. to 350° C. | (ramp at 4° C./min) |
| 350° C. | (30 min) |
| 350° C. to 450° C. | (ramp at 5° C./min) |
| 450° C. | (20 min) |
| 450° C. to 40° C. | (cooling at 8° C./min) |

### Comparative Example A

An identical procedure as described in Example 1 was used, except that no TiO₂ filler was added to the prepolymer solution. The final viscosity, before casting, was 993 poise.

### Example 2

The same procedure as described in Example 1 was used, except that 69.4 g of BPDA/PPD prepolymer (17.5 wt % in DMAC) was combined with 5.85 g of TiO₂ (FTL-200, Ishihara USA). The final viscosity of the formulation prior to casting was 524 poise.

### Example 3

The same procedure as described in Example 1 was used, except that 69.4 g of BPDA/PPD prepolymer was combined with 5.85 g of acicular TiO₂ (FTL-300, Ishihara USA). The final viscosity prior to casting was 394 poise.

### Example 4A

The same procedure as described in Example 1 was used, except that 69.3 g of BPDA/PPD prepolymer (17.5 wt % in DMAC) was combined with 5.62 g of acicular TiO₂ (FTL-100, Ishihara USA).

The material was filtered through 80 micron filter media (Millipore, polypropylene screen, 80 micron, PP 8004700) before the addition of the PMDA solution in DMAC.

The final viscosity before casting was 599 poise.

### Example 4

The same procedure as described in Example 1 was followed, except that 139 g of BPDA/PPD prepolymer (17.5 wt % in DMAC) was combined with 11.3 g of acicular TiO₂ (FTL-100). The mixture of BPDA/PPD prepolymer with acicular TiO₂ (FTL-110) was placed in a small container. A Silverson Model L4RT high-shear mixer (Silverson Machines, LTD, Chesham Baucks, England) equipped with a square-hole, high-shear screen was used to mix the formulation (with a blade speed of approximately 4000 rpm) for 20 minutes. An ice bath was used to keep the formulation cool during the mixing operation.

The final viscosity of the material before casting was 310 poise.

### Example 5

The same procedure as described in Example 4 was used, except that 133.03 g of BPDA/PPD prepolymer (17.5 wt % in DMAC) was combined with 6.96 g of acicular TiO₂ (FTL-110).

The material was placed a small container and mixed with a high-shear mixer (with a blade speed of approximately 4000 rpm) for approximately 10 min. The material was then filtered through 45 micron filter media (Millipore, 45 micron polypropylene screen, PP4504700).

The final viscosity was approximately 1000 poise, prior to casting.

### Example 6

The same procedure as described in Example 5 was used, except that 159.28 g of BPDA/PPD prepolymer was combined with 10.72 g of acicular TiO₂ (FTL-110). The material was mixed with a high-shear mixer for 5-10 minutes.

The final formulation viscosity prior to casting was approximately 1000 poise.

### Example 7

The same procedure as described in Example 5 was used, except that 157.3 g of BPDA/PPD prepolymer was combined with 12.72 grams of acicular TiO₂ (FTL-110). The material was blended with the high shear mixer for approximately 10 min.

The final viscosity prior to casting was approximately 1000 poise.

### Example 8

A procedure similar to that described in Example 5 was used, except that 140.5 g of DMAC was combined with 24.92 g of TiO₂ (FTL-110). This slurry was blended using a high-shear mixer for approximately 10 minutes.

This slurry (57.8 g) was combined with 107.8 g of BPDA/PPD prepolymer (17.5 wt % in DMAC) in a 250 ml, 3-neck, round-bottom flask. The mixture was slowly agitated with a paddle stirrer overnight under a slow nitrogen purge. The material was blended with the high-shear mixer a second time (approximately 10 min, 4000 rpm) and then filtered through 45 micron filter media (Millipore, 45 micron polypropylene, PP4504700).

The final viscosity was 400 poise.

### Example 9

The same procedure as described in Example 8 was used, except that 140.49 g of DMAC was combined with 24.89 g of talc (Flex Talc 610, Kish Company, Mentor, Ohio). The material was blended using the high-shear mixing procedure described in Example 8.

This slurry (69.34 g) was combined with 129.25 g of BPDA/PPD prepolymer (17.5 wt % in DMAC), mixed using a high-shear mixer a second time, and then filtered through 25 micron filter media (Millipore, polypropylene, PP2504700) and cast at 1600 poise.

### Example 10

This formulation was prepared at a similar volume % (with TiO₂, FTL-110) to compare with Example 9. The same procedure as described in Example 1 was used. 67.01 g of BPDA/PPD prepolymer (17.5 wt %) was combined with 79.05 grams of acicular TiO₂ (FTL-110) powder. The formulation was finished to a viscosity of 255 poise before casting.

A Dynamic Mechanical Analysis (DMA) instrument was used to characterize the mechanical behavior of Comparative Example A and Example 10. DMA operation was based on the viscoelastic response of polymers subjected to a small oscillatory strain (e.g., 10 μm) as a function of temperature and time (TA Instruments, New Castle, Del., USA, DMA 2980). The films were operated in tension and multifrequency-strain mode, where a finite size of rectangular specimen was clamped between stationary jaws and movable jaws. Samples of 6-6.4 mm width, 0.03-0.05 mm thickness and 10 mm length in the MD direction were fastened with 3 in-lb torque force. The static force in the length direction was 0.05 N with autotension of 125%. The film was heated at frequency of 1 Hz from 0° C. to 500° C. at 3° C./min rate. The storage modulii at room temperature, 500 and 480° C. are recorded on Table 1.

The coefficient of thermal expansion of Comparative Example A and Example 10 were measured by thermomechanical analysis (TMA). A TA Instrument model 2940 was set up in tension mode and furnished with an N₂ purge of 30-50 ml/min rate and a mechanical cooler. The film was cut to a 2.0 mm width in the MD (casting) direction and clamped lengthwise between the film clamps allowing a 7.5-9.0 mm length. The preload tension was set for 5 grams force. The film was then subjected to heating from 0° C. to 400° C. at 10° C./min rate with 3 minutes hold, cooling back down to 0° C. and reheating to 400° C. at the same speed. The calculations of thermal expansion coefficient in units of μm/m-C (or ppm/° C.) from 60° C. to 400° C. were reported for the casting direction (MD) for the second heating cycle over 60° C. to 400° C., and also over 60° C. to 350° C.

A thermogravimetric analysis instrument (TA, Q5000) was used for sample measurements of weight loss. Measurements were performed in flowing nitrogen. The temperature program involved heating at a rate of 20° C./min to 500° C. The weight loss after holding for 30 minutes at 500° C. is calculated by normalizing to the weight at 200° C., where any adsorbed water was removed, to determine the decomposition of polymer at temperatures above 200° C.

TABLE 1

| | Storage | CTE, | TGA, % wt loss at |
|---|---|---|---|
| | Modulus | ppm/° C. | 500° C., 30 min, |
| | (DMA) at 500° C. | 400 C., | normalized to |
| Example # | (480° C.), MPa | (350° C.) | weight at 200 C. |
| 10 | 4000 (4162) | 17.9, (17.6) | 0.20 |
| Comparative A | Less than 200 | 11.8, (10.8) | 0.16 |
| | (less than 200) | | |

### Comparative Example B

The same procedure as described in Example 8 was used, with the following differences. 145.06 g of BPDA/PPD prepolymer was used (17.5 wt % in DMAC).

127.45 grams of Wallastonite powder (Vansil HR325, R. T. Vanderbilt Company, Norwalk Conn.) having a smallest dimension greater than 800 nanometers (as calculated using an equivalent cylindrical width defined by a 12:1 aspect ratio and an average equivalent spherical size distribution of 2.3 microns) was combined with 127.45 grams of DMAC and high shear mixed according to the procedure of Example 8.

145.06 g of BPDA/PPD prepolymer (17.5 wt % in DMAC) was combined with 38.9 grams of the high shear mixed slurry of wollastonite in DMAC. The formulation was high shear mixed a second time, according to the procedure of Example 8.

The formulation was finished to a viscosity of 3100 poise and then diluted with DMAC to a viscosity of 600 poise before casting.

### Measurement of High Temperature Creep

A DMA (TA Instruments Q800 model) was used for a creep/recovery study of film specimens in tension and customized controlled force mode. A pressed film of 6-6.4 mm width, 0.03-0.05 mm thickness and 10 mm length was clamped between stationary jaws and movable jaws in 3 in-lb torque force. The static force in the length direction was 0.005N. The film was heated to 460° C. at 20° C./min rate and held at 460° C. for 150 min. The creep program was set at 2 MPa for 20 min, followed by recovery for 30 min with no additional force other than the initial static force of (0.005N). The creep/recovery program was repeated for 4 MPa and 8 MPa and the same time intervals as that for 2 MPa.

In Table 2 below are tabulated the strain and the recovery following the cycle at 8 MPa (more precisely, the maximum stress being from about 7.4 to 8.0 MPa). The elongation is converted to a unitless equivalent strain by dividing the elongation by the starting film length. The strain at 8 MPa (more precisely, the maximum stress being from about 7.4 to 8.0 MPa) and 460° C. is tabulated, “emax”. The term “e max” is the dimensionless strain which is corrected for any changes in the film due to decomposition and solvent loss (as extrapolated from the stress free slope) at the end of the 8 MPa cycle (more precisely, the maximum stress being from about 7.4 to 8.0 MPa). The term “e rec” is the strain recovery immediately following the 8 MPa cycle (more precisely, the maximum stress being from about 7.4 to 8.0 MPa), but at no additional applied force (other than the initial static force of 0.005 N), which is a measure of the recovery of the material, corrected for any changes in film due to decomposition and solvent loss as measured by the stress free slope). The parameter, labeled “stress free slope”, is also tabulated in units of dimensionless strain/min and is the change in strain when the initial static force of 0.005 N is applied to the sample after the initial application of the 8 Mpa stress (more precisely, the maximum stress being from about 7.4 to 8.0 MPa). This slope is calculated based on the dimensional change in the film (“stress free strain”) over the course of 30 min following the application of the 8 MPa stress cycle (more precisely, the maximum stress being from about 7.4 to 8.0 MPa). Typically the stress free slope is negative. However, the stress free slope value is provided as an absolute value and hence is always a positive number.

The third column, e plast, describes the plastic flow, and is a direct measure of high temperature creep, and is the difference between e max and e rec.

In general, a material which exhibits the lowest possible strain (e max), the lowest amount of stress plastic flow (e plast) and a low value of the stress free slope is desirable.

TABLE 2

| | | | | | | Absolute | Wt | Vol |
|---|---|---|---|---|---|---|---|---|
| | | | e max | | Plastic | Value | fraction of | fraction |
| | | Applied | (strain at | | deformation | Stress | inorganic | inorganic |
| | | Stress | applied | | ((eplast) = e | Free Slope | filler in | filler in |
| Example | Additive | (MPA)* | stress) | e rec | max − e rec)) | (/min) | polyimide | polyimide* |
| Example 1 | TiO₂ | 7.44 | 4.26E−03 | 3.87E−03 | 3.89E−04 | 2.82E−06 | 0.338 | 0.147 |
| | (FLT-110) | | | | | | | |
| Comparative | None | 7.52 | 1.50E−02 | 1.40E−02 | 9.52E−04 | 9.98E−06 | | |
| Example A | | | | | | | | |
| Example 2* | TiO₂ | 4.64 | 3.45E−03 | 3.09E−03 | 3.67E−04 | 2.88E−06 | 0.346 | 0.152 |
| | (FLT-200) | | | | | | | |
| Example 3 | TiO₂ | 7.48 | 2.49E−03 | 2.23E−03 | 2.65E−04 | 1.82E−06 | 0.346 | 0.152 |
| | (FLT-300) | | | | | (82% lower | | |
| | | | | | | than | | |
| | | | | | | comparative | | |
| | | | | | | example) | | |
| Example 4 A | TiO₂ | 7.48 | 3.56E−03 | 3.18E−03 | 3.77E−04 | 3.40E−06 | 0.338 | 0.147 |
| | (FLT-100) | | | | | | | |
| Example 4 | TiO₂ | 7.45 | 2.42E−03 | 2.20E−03 | 2.16E−04 | 1.73E−06 | 0.338 | 0.147 |
| | (FLT-110) | | | | | | | |
| Example 5 | TiO₂ | 7.48 | 7.83E−03 | 7.05E−03 | 7.84E−04 | 5.61E−06 | 0.247 | 0.100 |
| | (FLT-110) | | | | | | | |
| Example 6 | TiO₂ | 7.46 | 4.35E−03 | 3.97E−03 | 3.82E−04 | 2.75E−06 | 0.297 | 0.125 |
| | (FLT-110) | | | | | | | |
| Example 7 | TiO₂ | 7.46 | 3.32E−03 | 3.02E−03 | 3.00E−04 | 1.98E−06 | 0.337 | 0.147 |
| | (FLT-110) | | | | | | | |
| Example 8 | TiO₂ | 8.03 | 3.83E−03 | 3.53E−03 | 2.97E−04 | 3.32E−06 | 0.337 | 0.146 |
| | (FLT-110) | | | | | | | |
| Example 9 | Talc | 8.02 | 5.65E−03 | 4.92E−03 | 7.23E−04 | 7.13E−06 | 0.337 | 0.208 |
| Example 10 | TiO₂ | 7.41 | 1.97 E−03 | 1.42E−04 | 2.66E−04 | 1.37E−06 | 0.426 | 0.200 |
| | (FTL-110) | | | | | | | |
| Comparative | Wollastonite | 8.02 | 1.07E−02 | 9.52E−03 | 1.22E−03 | 1.15E−05 | 0.255 | 0.146 |
| B | powder | | | | | | | |

*Maximum applied stress was in a range from 7.4 to 8.0 MPa, except for Example 2 which was conducted at 4.64 MPa

Table 2 provides filler loadings in both weight fraction and volume fraction. Filler loadings of similar volume fractions are generally a more accurate comparison of fillers, since filler performance tends to be primarily a function of space occupied by the filler, at least with respect to the present disclosure. The volume fraction of the filler in the films was calculated from the corresponding weight fractions, assuming a fully dense film and using these densities for the various components:
1.42 g/cc for density of polyimide; 4.2 g/cc for density of acicular TiO₂;
2.75 g/cc for density of talc; and 2.84 g/cc for wollastonite

### Example 11

168.09 grams of a polyamic acid (PAA) prepolymer solution prepared from BPDA and PPD in DMAC (dimethylacetamide) with a slight excess of PPD (15 wt % PAA in DMAC)) were blended with 10.05 grams of Flextalc 610 talc for 2 minutes in a Thinky ARE-250 centrifugal mixer to yield an off-white dispersion of the filler in the PAA solution.

The dispersion was then pressure-filtered through a 45 micron polypropylene filter membrane. Subsequently, small amounts of PMDA (6 wt % in DMAC) were added to the dispersion with subsequent mixing to increase the molecular weight and thereby the solution viscosity to about 3460 poise. The filtered solution was degassed under vacuum to remove air bubbles and then this solution was coated onto a piece of Duosubstrate® aluminum release sheet (˜9 mil thick), placed on a hot plate, and dried at about 80-100° C. for 30 min to 1 hour to a tack-free film.

The film was subsequently carefully removed from the substrate and placed on a pin frame and then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (about 30 wt % filler).

The approximately 1.9 mil (approximately 48 micron) film exhibited the following properties.
Storage modulus (E′) by Dynamic Mechanical Analysis (TA Instruments, DMA-2980, 5° C./min) of 12.8 GPa at 50° C. and 1.3 GPa at 480° C., and a Tg (max of tan delta peak) of 341° C.
Coefficient of thermal expansion (TA Instruments, TMA-2940, 10° C./min, up to 380° C., then cool and rescan to 380° C.) of 13 ppm/° C. and 16 ppm/° C. in the cast and transverse directions, respectively, when evaluated between 50-350° C. on the second scan.
Isothermal weight loss (TA Instruments, TGA 2050, 20° C./min up to 500° C. then held for 30 min at 500° C.) of 0.42% from beginning to end of isothermal hold at 500° C.

### Comparative Example C

200 grams of a polyamic acid (PAA) prepolymer solution prepared from BPDA and PPD in DMAC with a slight excess of PPD (15 wt % PAA in DMAC,) were weighed out. Subsequently, small amounts of PMDA (6 wt % in DMAC) were added stepwise in a Thinky ARE-250 centrifugal mixer to increase the molecular weight and thereby the solution viscosity to about 1650 poise. The solution was then degassed under vacuum to remove air bubbles and then this solution was coated onto a piece of Duosubstrate® aluminum release sheet (˜9 mil thick), placed on a hot plate and dried at about 80-100° C. for 30 min to 1 hour to a tack-free film. The film was subsequently carefully removed from the substrate and placed on a pin frame then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (0 wt % filler).

The approximately 2.4 mil (approximately 60 micron) film exhibited the following properties.
Storage modulus (E′) by Dynamic Mechanical Analysis (TA Instruments, DMA-2980, 5° C./min) of 8.9 GPa at 50° C., and 0.3 GPa at 480° C., and a Tg (max of tan delta peak) of 348° C.
Coefficient of thermal expansion (TA Instruments, TMA-2940, 10° C./min, up to 380° C., then cool and rescan to 380° C.) of 18 ppm/° C. and 16 ppm/° C. in the cast and transverse directions, respectively, when evaluated between 50-350° C. on the second scan.
Isothermal weight loss (TA Instruments, TGA 2050, 20° C./min up to 500° C. then held for 30 min at 500° C.) of 0.44% from beginning to end of isothermal hold at 500° C.

### Example 12

In a similar manner to Example 11, a polyamic acid polymer with Flextalc 610 at about 30 wt % was cast onto a 5 mil polyester film. The cast film on the polyester was placed in a bath containing approximately equal amounts of acetic anhydride and 3-picoline at room temperature. As the cast film imidized in the bath, it began to release from the polyester. At this point, the cast film was removed from the bath and the polyester, placed on a pinframe, and then placed in a oven and ramped as described in Example 11. The resulting talc-filled polymide film exhibited a CTE by TMA (as in Example 11) of 9 ppm/° C. and 6 ppm/° C. in the cast and transverse directions, respectively.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and any figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

When an amount, concentration, or other value or parameter is given as either a range, preferred range or a list of upper values and lower values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

What is claimed is:

1. A process for forming at least one photovoltaic cell or photovoltaic cell precursor upon a substrate, comprising:
depositing on the substrate at least one of the group consisting of:
a transparent conductive oxide layer,
an electrode layer,
an absorber layer,
a window layer, and
a collector layer
wherein the substrate comprises:
a) a polyimide in an amount from 40 to 95 weight percent of the layer, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
a) is less than 800 nanometers in at least one dimension;
b) has an aspect ratio greater than 3:1;
c) is less than the thickness of the film in all dimensions; and
d) is present in an amount from 5 to 60 weight percent of the total weight of the film,
the substrate having a thickness from 4 to 150 microns.

2. A process according to claim 1 wherein least two of the group consisting of:
a transparent conductive oxide layer,
an electrode layer,
an absorber layer,
a window layer, and
a collector layer
are deposited upon the substrate.

3. A process according to claim 1 wherein least three of the group consisting of:
a transparent conductive oxide layer,
an electrode layer,
an absorber layer,
a window layer, and
a collector layer
are deposited upon the substrate.

4. A process according to claim 1 wherein least three of the group consisting of:
a transparent conductive oxide layer,
an electrode layer,
an absorber layer,
a window layer, and
a collector layer
are deposited upon the substrate.

5. A process according to claim 1 wherein least four of the group consisting of:
a transparent conductive oxide layer,
an electrode layer,
an absorber layer,
a window layer, and
a collector layer
are deposited upon the substrate.

6. A process according to claim 1 wherein least five of the group consisting of:
a transparent conductive oxide layer,
an electrode layer,
an absorber layer,
a window layer, and
a collector layer
are deposited upon the substrate.

7. A process according to claim 1 wherein the deposition is conducted at a temperature of 500° C. or less.

8. A process according to claim 1 wherein the deposition is conducted at a temperature of 475° C. or less.

9. A process according to claim 1 wherein the deposition is conducted at a temperature of 450° C. or less.

10. A process according to claim 1 wherein deposition is effected on a continuous web of substrate.

11. A process according to claim 10 wherein the continuous web of substrate is a component of a reel to reel process.

12. A process according to claim 1 wherein the filler is a platelet, needle-like or fibrous and the semiconductor material is amorphous silicon.

13. A process according to claim 1 wherein the filler is needle-like or fibrous.

14. A process according to claim 1 wherein the filler is smaller than 600 nm in at least one dimension.

15. A process according to claim 1 wherein the filler is smaller than 400 nm in at least one dimension.

16. A process according to claim 1 wherein the filler is smaller than 200 nm in at least one dimension.

17. A process according to claim 1 wherein the filler comprises oxygen and at least one member of the group consisting of aluminum, silicon, titanium, magnesium and combinations thereof.

18. A process according to claim 1 wherein the filler comprises acicular titanium dioxide.

19. A process according to claim 1 wherein the filler comprises an acicular titanium dioxide, at least a portion of which is coated with an aluminum oxide and the semiconductor material comprises amorphous silicon.

20. A process according to claim 1 wherein:
a) the rigid rod type dianhydride is selected from a group consisting of 3,3′,4,4′-biphenyl tetracarboxylic dianhydride (BPDA), pyromellitic dianhydride (PMDA), and mixtures thereof;
and
b) the rigid rod type diamine is selected from 1,4-diaminobenzene (PPD), 4,4′-diaminobiphenyl, 2,2′-bis(trifluoromethyl) benzidene (TFMB), 1,5-naphthalenediamine, 1,4-naphthalenediamine, and mixtures thereof.

21. A process according to claim 1 wherein the filler is selected from a group consisting of oxides, nitrides, carbides and combinations thereof.

22. A process according to claim 1 wherein at least 25 mole percent of the diamine is 1,5-naphthalenediamine.

23. A process according to claim 1 wherein the support layer comprises a coupling agent, a dispersant or a combination thereof.

24. A process according to claim 1 wherein the filler is selected from a group consisting of oxides, nitrides, carbides and mixtures thereof, and the film has the following properties: (i) a Tg greater than 300° C., (ii) a dielectric strength greater than 500 volts per 25.4 microns, (iii) an isothermal weight loss of less than 1% at 500° C. over 30 minutes, (iv) an in-plane CTE of less than 25 ppm/° C., (v) an absolute value stress free slope of less than 10 times (10)⁻⁶ perminute, and (vi) an eₘₐₓ of less than 1% at 7.4-8 MPa.

25. A process according to claim 1 wherein the film comprises two or more layers.

26. A process according to claim 1 wherein the film is reinforced with a thermally stable, inorganic: fabric, paper, sheet, scrim or a combination thereof.

27. A composite film comprising a substrate supporting at least one of the group consisting of:
a transparent conductive oxide layer,
an electrode layer,
an absorber layer,
a window layer, and
a collector layer
wherein the substrate comprises:
a) a polyimide in an amount from 40 to 95 weight percent of the layer, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
a) is less than 800 nanometers in at least one dimension;
b) has an aspect ratio greater than 3:1;
c) is less than the thickness of the film in all dimensions; and
d) is present in an amount from 5 to 60 weight percent of the total weight of the film,
the substrate having a thickness from 4 to 150 microns.

28. A composite film in accordance with claim 27, comprising at least two of the group consisting of:
a transparent conductive oxide layer,
an electrode layer,
an absorber layer,
a window layer, and
a collector layer.

29. A composite film in accordance with claim 27, comprising at least three of the group consisting of:
a transparent conductive oxide layer,
an electrode layer,
an absorber layer,
a window layer, and
a collector layer.

30. A composite film in accordance with claim 27, comprising at least four of the group consisting of:
a transparent conductive oxide layer,
an electrode layer,
an absorber layer,
a window layer, and
a collector layer.

31. A composite film in accordance with claim 27, comprising:
a transparent conductive oxide layer,
an electrode layer,
an absorber layer,
a window layer, and
a collector layer.

32. A composite film in accordance with claim 27, wherein the filler is a platelet, needle-like or fibrous filler and the semiconductor material is amorphous silicon.

33. A composite film in accordance with claim 27, wherein the filler is smaller than 400 nm in at least one dimension.

34. A composite film in accordance with claim 27, wherein the filler comprises acicular titanium dioxide.

35. A composite film in accordance with claim 27, wherein the filler comprises an acicular titanium dioxide, at least a portion of which is coated with an aluminum oxide.

36. A composite film in accordance with claim 27, wherein:
a) the rigid rod type dianhydride is selected from a group consisting of 3,3′,4,4′-biphenyl tetracarboxylic dianhydride (BPDA), pyromellitic dianhydride (PMDA), and mixtures thereof;
and
b) the rigid rod type diamine is selected from 1,4-diaminobenzene (PPD), 4,4′-diaminobiphenyl, 2,2′-bis(trifluoromethyl) benzidene (TFMB), 1,5-naphthalenediamine, 1,4-naphthalenediamine, and mixtures thereof.

37. A composite film in accordance with claim 27, wherein the support layer comprises a coupling agent, a dispersant or a combination thereof.

38. A composite film in accordance with claim 27, wherein the filler is selected from a group consisting of oxides, nitrides, carbides and mixtures thereof, and the film has the following properties: (i) a Tg greater than 300° C., (ii) a dielectric strength greater than 500 volts per 25.4 microns, (iii) an isothermal weight loss of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

39. A composite film in accordance with claim 27, wherein the film comprises two or more layers.

40. A composite film in accordance with claim 27, wherein the film is reinforced with a thermally stable, inorganic: fabric, paper, sheet, scrim or a combination thereof.
